(19) United States
(12) Patent Application Publication
(10) Pub. No.: US 2025/0133964 A1
(43) Pub. Date: Apr. 24, 2025

(54) THERMOELECTRIC GENERATOR

(71) Applicant: STMicroelectronics International N.V., Geneva (CH)

(72) Inventors: Flavio Francesco VILLA, Milano (IT); Francesco FONCELLINO, Casagiove (IT); Marco DEL SARTO, Monza (IT)

(73) Assignee: STMicroelectronics International N.V., Geneva (CH)

(21) Appl. No.: 18/915,705

(22) Filed: Oct. 15, 2024

(30) Foreign Application Priority Data
Oct. 23, 2023 (IT) 102023000022077

(51) Int. Cl. H10N 10/17; H02S 10/10

(52) U.S. Cl. CPC H10N 10/17; H02S 10/10

(57) ABSTRACT

A thermoelectric generator includes a thermoelectric converter and a thermal coupling structure, configured to thermally couple the thermoelectric converter to a first body at a first temperature and to a second body at a second temperature, lower than the first temperature. The thermoelectric converter includes a support body, having a structural layer and a thermal insulation layer, and a plurality of thermopiles arranged on the thermal insulation layer and thermally coupled to the thermal coupling structure. The thermal insulation layer has a thickness such as to thermally insulate the thermopiles from the structural layer and the support body is continuous and without cavities between the thermopiles and a face of the structural layer opposite to the thermopiles.

### BACKGROUND

### Technical Field

The present disclosure relates to a thermoelectric generator.

### Description of the Related Art

As is known, systems for harvesting energy (also known as energy harvesting or energy scavenging systems) from environmental energy sources have aroused and continue to arouse considerable interest in various fields of technology. Typically, energy harvesting systems are for harvesting, storing, and transferring energy generated by mechanical, thermal or chemical sources to a generic electrical load. In this manner, the electrical load does not use batteries or other power supply systems which are often bulky and poorly resistant to mechanical stresses and entail maintenance costs for replacement interventions.

Environmental energy may be harvested from different available sources and converted into electrical energy using appropriate transducers. For example, available energy sources may be mechanical or acoustic vibrations or, more generally, forces or pressures, chemical energy sources, electromagnetic fields, ambient light, thermal energy sources. For harvesting and conversion, for example, electrochemical, electromechanical, piezoelectric, electroacoustic, electromagnetic, photoelectric, electrostatic, thermoelectric, thermoacoustic, thermomagnetic, thermionic transducers may be used.

Thermoelectric generators or TEGs exploit the thermoelectric effect between pairs of different conductors in presence of a temperature difference between a hot body and a cold body to produce an electrical quantity.

The known thermoelectric generators, also to meet the miniaturization demands of the market, may be provided exploiting semiconductor processing techniques. In particular, the thermoelectric effect may be obtained with series of P-type and N-type semiconductor material strips alternate and arranged as a serpentine.

The strips extend between a heat source or hot body and a heat sink or cold body and each strip has, at its ends, junctions with strips of opposite type. Therefore, junctions between consecutive strips are alternately coupled to the heat source and heat sink. To obtain that the thermal coupling to the external environment is substantially limited to the heat sink and the heat source, the strips are often formed on membranes integrated into semiconductor dice and suspended on cavities. Each die is then bonded to a support board, for example a PCB, with the cavity delimited on one side by the membrane and on the other by the support board. However, the thermoelectric generators thus formed suffer from structural weaknesses. In particular, the packaging of thermoelectric generators includes a molding step wherein a resin is injected from above the membrane and embeds the die. However, resin injection may quite frequently cause mechanical breakdown of the membrane and, consequently, a relatively high number of rejects.

### BRIEF SUMMARY

The present disclosure to provides a thermoelectric generator which allows the limitations described to be overcome or at least attenuated.

According to the present disclosure, the thermoelectric generator includes a thermoelectric converter and a thermal coupling structure thermally coupling the thermoelectric converter to a first body at a first temperature and to a second body at a second temperature lower than the first temperature. The thermoelectric converter includes a support body, including a structural layer and a thermal insulation layer; and a plurality of thermopiles arranged on the thermal insulation layer and thermally coupled to the thermal coupling structure, wherein the thermal insulation layer thermally insulates the thermopiles from the structural layer, and the support body is continuous and without cavities between the thermopiles and a face of the structural layer opposite to the thermopiles.

### BRIEF DESCRIPTION OF THE SEVERAL VIEWS OF THE DRAWINGS

For a better understanding of the present disclosure, preferred embodiments are presented, by way of non-limiting example, with reference to the attached drawings, wherein:

FIG. 1 is a block diagram of an environmental energy harvesting system;

FIG. 2 is a cross-section through a thermoelectric generator in accordance with an embodiment of the present disclosure, incorporated into the environmental energy harvesting system of FIG. 1;

FIG. 3 is a top-plan view, with parts removed for clarity, of the thermoelectric generator of FIG. 2; and

FIG. 4 is an enlarged view of a detail of FIG. 3, wherein parts have been dashed for clarity.

### DETAILED DESCRIPTION

The following description refers to the arrangement shown; consequently, expressions such as “above”, “below”, “upper”, “lower”, relate to the attached Figures and should not be interpreted in a limiting manner.

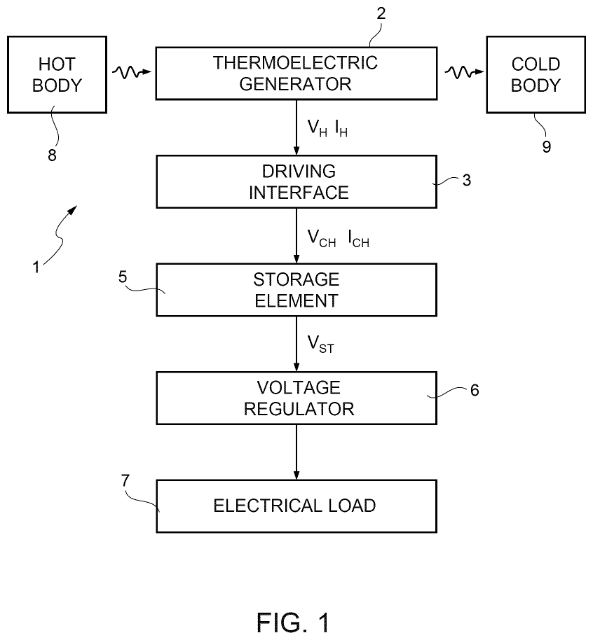

Referring to FIG. 1, an environmental energy harvesting system, indicated as a whole with the number 1, comprises a thermoelectric generator 2, a driving interface 3, a storage element 5 and a voltage regulator 6. Furthermore, an output of the voltage regulator 6 powers an electrical load 7.

The thermoelectric generator 2 is thermally coupled between a first body 8 (in this case a hot body or heat source at a higher temperature) and a second body 9 (in this case a cold body at a lower temperature) and uses the temperature difference between the first body 8 and the second body 9 to provide harvesting electrical quantities, in particular a harvesting voltage V_{H} and a harvesting current I_{H}.

The driving interface 3 receives the harvesting voltage V_{H} and the harvesting current I_{H} from the thermoelectric generator 2 and provides charge electrical quantities, in particular a charge voltage VCH and a charge current I_{CH}, to the storage element 5. The energy stored in the storage element 5 increases due to the energy transferred thanks to the charge voltage VCH and the charge current I_{CH} and determines a storage voltage V_{ST} in accordance with the charging profile of the same storage element 5.

The voltage regulator 6 receives the storage voltage V_{ST} and provides a regulated supply voltage V_{DD} to the electrical load 7.

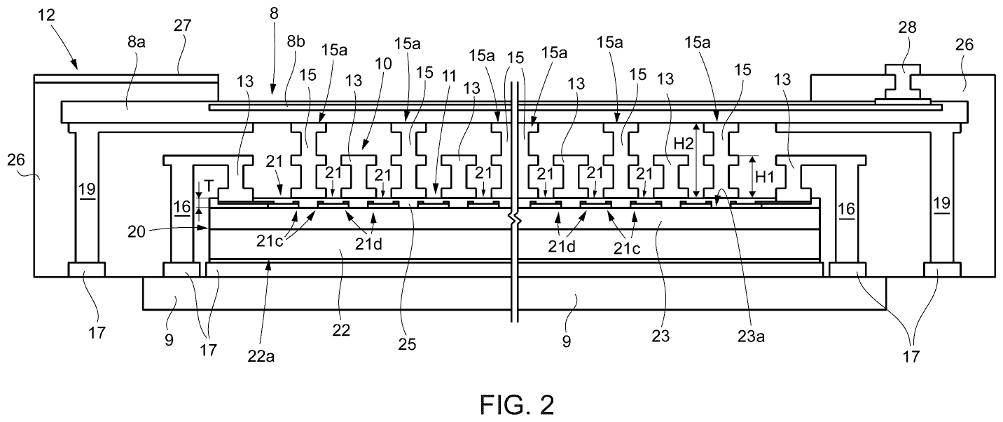

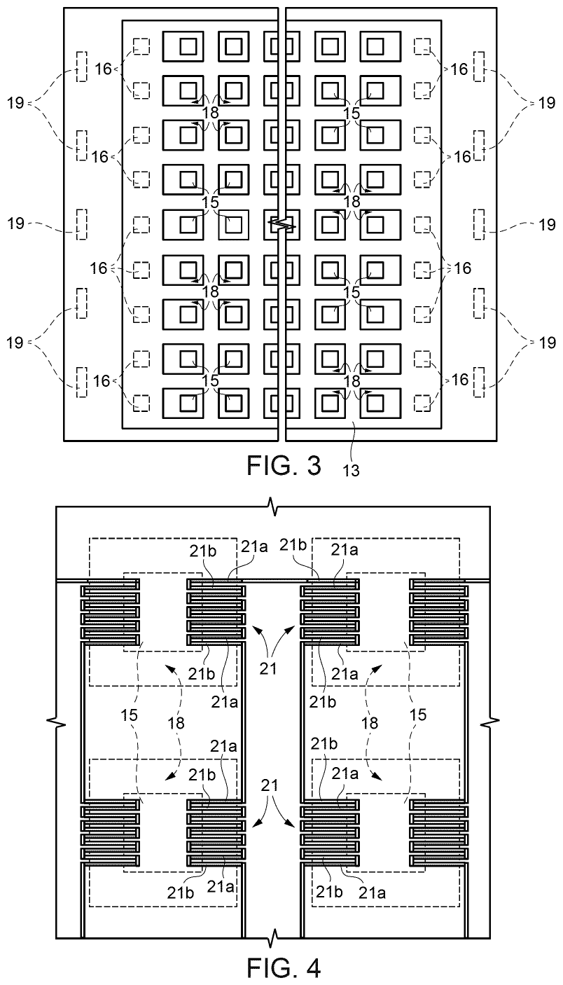

FIGS. 2 and 3 show in more detail the thermoelectric generator 2, which, in one embodiment, comprises a thermal coupling structure 10, a thermoelectric converter 11 and a package 12. FIG. 2 also illustrates the first body 8 and the second body 9, which are integrated into the thermoelectric generator 2 and, in one embodiment, they are respectively defined by (and so they will be referred to as hereinbelow) a photovoltaic cell and a heat sink. It is understood, however, that the hot body and the cold body may be defined by other structures. For example, the hot body may be a chip integrating a processing unit that produces heat to be dissipated. The photovoltaic cell 8 and the heat sink 9 are arranged on opposite faces of the thermoelectric generator 2. The photovoltaic cell 8, which comprises a P-region 8a and an N-region 8b, is partly incorporated into the package 12 and has an active area exposed to the external light radiation.

The thermal coupling structure 10 couples the thermoelectric converter 11 on one side (hot side) to the photovoltaic cell 8 and on the other (cold side) to the heat sink 9. In more detail, the thermal coupling structure 10 comprises a grid 13 and columns 15 formed of a thermally conductive material, for example copper. The grid 13 is placed in contact with the thermoelectric converter 11 and is thermally coupled to the heat sink 9 through plugs 16, also of copper, and to a metal structure, for example a lead frame 17, bonded to the heat sink 9. The lead frame 17 defines a thermal coupling interface for thermally coupling the thermoelectric generator 2 to the heat sink 9. The plugs 16, in particular their thermal resistance, are sized so that the grid 13 is substantially at the temperature of the heat sink 9. The grid 13 therefore defines a cold side of the thermoelectric converter 11. The plugs 16 and the lead frame 17 are also used (in a manner not illustrated) for the electrical connection to the outside, in particular to the voltage regulator 6 and to the load 7. Furthermore, the grid 13 extends up to a first height H1 from the thermoelectric converter 11, without reaching the photovoltaic cell 8.

The grid 13 has a plurality of through openings 18 arranged in a matrix and each column 15 extends through a respective opening 18 without contact with the grid 13. The empty/full ratio of the grid 13, i.e., the ratio between the sum of the areas (in-plan view) of all the openings 18 and the area of the solid portion of the grid 13 in contact with the thermoelectric converter 11 is advantageously comprised between ⅕ and ½ and in one embodiment is about ⅓.

The columns 15 are in contact with the thermoelectric converter 11 and extend up to a second height H2 greater than the first height H1 and such as to reach the photovoltaic cell 8. First ends of the columns 15 are thermally coupled to the thermoelectric converter 11, as explained in detail hereinbelow. Second ends of the columns 15 are thermally coupled to the photovoltaic cell 8 and define a thermal coupling interface 15a for the thermal coupling of the thermoelectric generator 2 to the photovoltaic cell 8, which defines the hot body. The columns 15 are sized so as to maintain thermal coupling portions of the thermoelectric converter 11 substantially at the temperature of the photovoltaic cell 8 and therefore define a hot side for the thermoelectric converter 11. At least in an intermediate manufacturing step, before forming the package 12, the columns 15 also have a mechanical support function towards the photovoltaic cell 8.

Furthermore, the photovoltaic cell 8 is electrically coupled to a respective portion of the lead frame 17 through plugs 19, of the same material as the grid 13 and the columns 15, to receive in use a reference voltage, for example a ground voltage, which may also be the reference voltage of the thermoelectric converter 11. The plugs 19 are sized so as to ensure electrical coupling, but, at the same time, hinder the heat loss from the hot part of the device, i.e., the non-exposed face of the photovoltaic cell 8, to the outside.

The thermoelectric converter 11 comprises a support body 20 and a plurality of thermopiles 21 arranged on the support body 13.

The support body 20 comprises a semiconductor structural layer 22, a thermal insulation layer 23 on the semiconductor layer 21 and a dielectric layer 25, having the thermopiles 21 embedded therein.

The semiconductor structural layer 22, for example monocrystalline silicon, has a mechanical support function and provides a mechanical coupling interface 22a to the lead frame 17 for the thermoelectric converter 11.

The thermal insulation layer 23 is a dielectric layer of sufficient thickness to thermally insulate the thermopiles 21 from the semiconductor structural layer 22, for example a silicon oxide layer of thickness greater than 15 μm, for example 18 μm.

The thermopiles 21 are arranged on a face 23a of the thermal insulation layer 23 opposite to the semiconductor structural layer 22 and are embedded in the dielectric layer 25.

The structure of the support body 20 having the thermopiles 21 lying thereon is therefore continuous and without cavities between the thermoelectric converter 11 and a face 22a of the semiconductor structural layer 22 opposite to the thermopiles 21.

The grid 13 and the columns 15 of the thermal coupling structure 10 are in contact with a face of the dielectric layer 25 opposite to the thermal insulation layer 23. Consequently, the grid 13 and the columns 15 are not in contact with the thermopiles 21 so that there is electrical insulation. The thickness T of the dielectric layer 25 is however selected so as to have thermal coupling between the thermopiles 21 and the thermal coupling structure 10 as described in more detail hereinbelow.

Also referring to FIG. 4, two thermopiles 21 are associated with each column 15, on opposite sides. In more detail, each thermopile 21 comprises a plurality of first semiconductor strips 21a, for example of N-type polycrystalline silicon, and a plurality of second semiconductor strips 21b, for example of P-type polycrystalline silicon, which extend alternate in series as a serpentine between the respective column 15 and portions of the grid 13 facing it across the respective opening 18. The first semiconductor strips 21a and the second semiconductor strips 21b form hot junctions 21c in proximity to the respective columns 15 and cold junctions 21d in proximity to the grid 13. Thermopiles 21 on the edges of the thermoelectric converter 11 are also electrically coupled to the grid 13 and, through the grid 13, to respective plugs 16 to provide the generated electrical quantities to the outside.

In the embodiment of FIGS. 3 and 4, the thermopiles 21 are electrically coupled in series. However, it is understood that the number, the arrangement and the electrical connection of the thermopiles 21 on the support body 13 may be different from what is described below, in accordance with design preferences.

The package 12 comprises a body 26 of polymeric material, for example a resin, and accessory elements functional to the photovoltaic cell 8, such as a mirror surface portion 27 and electrical connections 28.

The body 26 embeds the thermal coupling structure 10, the thermoelectric converter 11 and part of the photovoltaic cell 8, which is therefore integrated into the thermoelectric generator 2 in the embodiment described. The mirror surface portion 27 surrounds part of the photovoltaic cell 8 to improve its efficiency. The electrical connections 28 traverse an upper part of the body 25 to contact the N-region 8b of the photovoltaic cell 8. The P-region 8a is instead maintained at the reference voltage through the plug 19 connected to the lead frame 17.

The thermoelectric generator according to the disclosure has different advantages.

Firstly, the thermoelectric generator is robust from a mechanical point of view and little subject to breakdown, because the thermal insulation is obtained without using membranes. The thermal insulation layer has in fact a dual function. On the one hand, the thermopiles of the thermoelectric converter are decoupled from the underlying components, in particular from the cold body, to ensure that there is a suitable temperature difference between the hot junctions and the cold junctions. On the other hand, the thermal insulation layer offers a robust support without cavities for the thermopiles. The continuous structure without cavities eliminates the criticalities of the membranes and is particularly advantageous in the resin injection step during the molding of the package. The number of rejects may be significantly reduced to the benefit of the yield of the manufacturing processes.

Furthermore, the support body may be easily produced using conventional semiconductor processing techniques and the manufacturing process is much simpler and cheaper than the processes used to manufacture membranes.

The thermal coupling structure is also simple to form.

A further advantage results from the use of a photovoltaic cell as a heat source. The conversion efficiency of photovoltaic cells is in fact relatively low and a large part of the energy received from the impinging light radiation is transformed into heat and lost into the environment. The coupling with the thermoelectric generator allows part of the heat produced by the photovoltaic cell to be converted into electrical energy, significantly improving the overall efficiency of the device.

Finally, it is clear that modifications and variations may be made to the thermoelectric generator and the environmental energy harvesting system described, without departing from the scope of the present disclosure, as defined in the attached claims.

For example, the operation of the thermoelectric generator may be reversible. In practice, the first body may be at a lower temperature (cold body) and the second body may be at a higher temperature (hot body). For the operation, in fact, it is generally sufficient for a certain temperature difference to be ensured, so that, due to the Seebeck effect, the thermopiles are in a condition to produce a suitable voltage. The sign of the voltage may be determined by which, of the first body and the second body, define the hot body and the cold body, but in principle the sign is indifferent. Possibly, the thermoelectric generator may be sized to optimize the reverse operation, according to design preferences.

The hot body may be different from a photovoltaic cell. In fact, the described thermoelectric generator may be coupled to any heat source useful to produce a sufficient temperature difference. For example, the heat source may be an electronic component, such as a processing unit, which tends to overheat or in any case generate heat during operation.

A thermoelectric generator is summarized as including: a thermoelectric converter (11); and a thermal coupling structure (10), configured to thermally couple the thermoelectric converter (11) to a first body (8) at a first temperature and to a second body (9) at a second temperature, lower than the first temperature; wherein the thermoelectric converter (11) comprises a support body (20), including a structural layer (22) and a thermal insulation layer (23), and a plurality of thermopiles (21) arranged on the thermal insulation layer (23) and thermally coupled to the thermal coupling structure (10); wherein the thermal insulation layer (23) has such a thickness as to thermally insulate the thermopiles (21) from the structural layer (22); and wherein the support body (20) is continuous and without cavities between the thermopiles (21) and a face (22a) of the structural layer (22) opposite to the thermopiles (21).

The thermal insulation layer (23) is a silicon oxide layer with a thickness greater than 15 μm.

The thermal coupling structure (10) includes a thermally conductive grid (13) placed in contact with the thermoelectric converter (11) and thermally coupled to first junctions (21d) of the thermopiles (21).

The thermal coupling structure (10) includes thermally conductive columns (15) having first ends, thermally coupled to second junctions (21c) of the thermopiles (21) and second ends defining a first interface (15a) for the thermal coupling to the first body (8).

The grid (13) is thermally coupled to a second interface (17) for the thermal coupling to the second body (9).

The grid (13) has a plurality of through openings (18) arranged in a matrix and each column (15) extends through a respective opening (18) without contact with the grid (13).

An empty/full ratio of the grid (13) is comprised between ⅕ and ½.

Each thermopile (21) is associated with a respective one of the columns (15) and includes a plurality of first semiconductor strips (21a), having a first conductivity type, and a plurality of second semiconductor strips (21b), having a second conductivity type; wherein the first semiconductor strips (21a) and the second semiconductor strips (21b) extend alternate in series between the respective column (15) and portions of the grid (13) facing the respective column (15) through the respective opening (18); and wherein the first semiconductor strips (21a) and the second semiconductor strips (21b) form the first junctions (21d) at the respective column and the second junctions (21c) at the portions of the grid (13) facing the respective column (15) through the respective opening (18).

A plurality of thermopiles (21) is associated with each column (15).

The support body (20) includes a dielectric layer (25) and wherein the thermopiles (21) are arranged on one face (23a) of the thermal insulation layer (23) opposite to the structural layer (22) and are embedded in the dielectric layer (25).

The grid (13) and the columns (15) of the thermal coupling structure (10) are in contact with a face of the dielectric layer (25) opposite to the thermal insulation layer (23) and wherein a thickness (T) of the dielectric layer (25) is selected so as to have thermal coupling between the thermopiles (21) and the thermal coupling structure (10).

The grid (13) extends up to a first height (H1) from the thermoelectric converter (11), at a distance from the first body (9), and the columns (15) extend up to a second height (H2) from the thermoelectric converter (11), the second height (H2) being greater than the first height (H1) and such as to reach the first body (8).

The grid (13) is electrically conductive and provided with an electrical connection (16) to the outside and wherein at least one of the thermopiles (21) is electrically coupled to the grid (13).

The thermoelectric generator includes a polymeric material body (25), wherein the thermal coupling structure (10) and the thermoelectric converter (11) are at least partly incorporated into the polymeric material body (25).

An environmental energy harvesting system includes a hot body (8) at a first temperature, a cold body (9) at a second temperature different from the first temperature, and a thermoelectric generator (2) according to any of the preceding claims thermally coupled between the first body (8) and the second body (9).

The first body (8) is a heat source and includes a photovoltaic cell.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thermoelectric generator, comprising:
a thermoelectric converter; and
a thermal coupling structure thermally coupling the thermoelectric converter to a first body at a first temperature and to a second body at a second temperature lower than the first temperature, the thermoelectric converter including:
a support body, including a structural layer and a thermal insulation layer; and
a plurality of thermopiles arranged on the thermal insulation layer and thermally coupled to the thermal coupling structure,
wherein the thermal insulation layer thermally insulates the thermopiles from the structural layer, and the support body is continuous and without cavities between the thermopiles and a face of the structural layer opposite to the thermopiles.

2. The thermoelectric generator according to claim 1, wherein the thermal insulation layer is a silicon oxide layer with a thickness greater than 15 μm.

3. The thermoelectric generator according to claim 1, wherein the thermal coupling structure comprises a thermally conductive grid in contact with the thermoelectric converter and thermally coupled to a plurality of first junctions of the thermopiles.

4. The thermoelectric generator according to claim 3, wherein the thermal coupling structure comprises a plurality of thermally conductive columns each having a first end, thermally coupled to a plurality of second junctions of the thermopiles and a second end defining a first interface for thermal coupling to the first body.

5. The thermoelectric generator according to claim 4, wherein the grid is thermally coupled to a second interface for thermal coupling to the second body.

6. The thermoelectric generator according to claim 4, wherein the grid has a plurality of through openings arranged in a matrix and each thermally conductive column extends through a respective opening without contact with the grid.

7. The thermoelectric generator according to claim 6, wherein a ratio of a sum of an area of the openings and a sum of an area of solid portions of the grid is in the range of ⅕ and ½.

8. The thermoelectric generator according to claim 6, wherein each thermopile is associated with a respective one of the columns and includes a plurality of first semiconductor strips having a first conductivity type and a plurality of second semiconductor strips having a second conductivity type, wherein the first semiconductor strips and the second semiconductor strips extend alternate in series between the respective column and portions of the grid facing the respective column through the respective opening, and wherein the first semiconductor strips and the second semiconductor strips form the first junctions at the respective column and the second junctions at the portions of the grid facing the respective column through the respective opening.

9. The thermoelectric generator according to claim 8, wherein a plurality of thermopiles is associated with each column.

10. The thermoelectric generator according to claim 3, wherein the support body comprises a dielectric layer and wherein the thermopiles are arranged on one face of the thermal insulation layer opposite to the structural layer and are embedded in the dielectric layer.

11. The thermoelectric generator according to claim 10, wherein the grid and the columns of the thermal coupling structure are in contact with a face of the dielectric layer opposite to the thermal insulation layer and wherein a thickness of the dielectric layer is selected so as to have thermal coupling between the thermopiles and the thermal coupling structure.

12. The thermoelectric generator according to claim 3, wherein the grid extends up to a first height from the thermoelectric converter, at a distance from the first body, and the columns extend up to a second height from the thermoelectric converter, the second height being greater than the first height and such as to reach the first body.

13. The thermoelectric generator according to claim 3, wherein the grid is electrically conductive and provided with an electrical connection to the outside and wherein at least one of the thermopiles is electrically coupled to the grid.

14. The thermoelectric generator according to claim 1, comprising a polymeric material body, wherein the thermal coupling structure and the thermoelectric converter are at least partly incorporated into the polymeric material body.

15. A device, comprising:
a thermoelectric converter having a first side opposite a second side along a first direction;
a photovoltaic cell on the first side of the thermoelectric converter;
a heat sink on the second side of the thermoelectric converter;
a thermal coupling structure coupled between the photovoltaic cell and the heat sink, the thermal coupling structure including:
a thermally conductive grid on the thermoelectric converter extending a first height along the first direction; and
a plurality of thermally conductive columns extending a second height greater than the first height along the first direction.

16. The device of claim 15, wherein the thermoelectric converter includes:
a support body;
a dielectric layer on the support body; and
a plurality of thermopiles embedded in the dielectric layer.

17. The device of claim 15, wherein the thermally conductive grid has a plurality of openings, each column of the plurality of thermally conductive columns extending through a respective opening.

18. A device, comprising:
a thermoelectric converter having a first side opposite a second side along a first direction and including:
a structural layer;
a plurality of thermopiles on the structural layer; and
an insulation layer thermally insulating the plurality of thermopiles from the structural layer;
a heat source on the first side of the thermoelectric converter;
a heat sink on the second side of the thermoelectric converter;
a thermal coupling structure coupled between the heat source and the heat sink, the thermal coupling structure including:
a thermally conductive grid on the thermoelectric converter extending a first height along the first direction;
a first plurality of plugs coupled between the thermoelectric converter and the heat sink; and
a plurality of thermally conductive columns extending a second height greater than the first height along the first direction, the plurality of thermally conductive columns being directly coupled to the heat source.

19. The device of claim 18, further comprising:
a lead frame coupled between the first plurality of plugs and the heat sink; and
a second plurality of plugs coupled between the lead frame and the heat source.

20. The device of claim 18, further comprising a dielectric layer on the insulation layer, the plurality of thermopiles being in the dielectric layer.
